(19) United States
(12) Patent Application Publication
(10) Pub. No.: US 2023/0088084 A1
(43) Pub. Date: Mar. 23, 2023

(54) METHOD OF PREPARING GRAPHYNE

(71) Applicants: Research & Business Foundation Sungkyunkwan University, Suwon-si (KR); INSTITUTE FOR BASIC SCIENCE, Daejeon (KR)

(72) Inventors: Hyoyoung LEE, Uiwang-si (KR); Sohyeon SEO, Suwon-si (KR); Jungsue CHOI, Suwon-si (KR)

(73) Assignees: Research & Business Foundation Sungkyunkwan University, Suwon-si (KR); INSTITUTE FOR BASIC SCIENCE, Daejeon (KR)

(21) Appl. No.: 17/869,360

(22) Filed: Jul. 20, 2022

(30) Foreign Application Priority Data
Jul. 21, 2021 (KR) 10-2021-0095877

(51) Int. Cl. C01B 32/05; H01L 29/16

(52) U.S. Cl. CPC C01B 32/05; H01L 29/16

(57) ABSTRACT

Disclosed is a method for preparing a graphyne including: supplying a precursor represented by the following Chemical Formula 1 to a chamber including a first zone and a second zone; vaporizing or subliming the precursor in the first zone; and depositing the precursor vaporized or sublimed in the second zone on a metal substrate to form the graphyne:

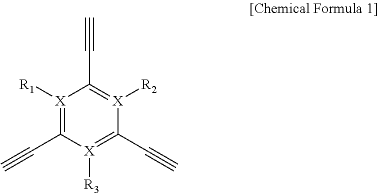

(in Chemical Formula 1, X is carbon or nitrogen, and R₁ to R₃ may be selected from the group consisting of hydrogen, bromine, fluorine, chlorine, and iodine, respectively).

### CROSS-REFERENCE TO RELATED APPLICATIONS

This application claims the benefit under 35 USC § 119(a) of Korean Patent Application No. 10-2021-0095877 filed on Jul. 21, 2021, in the Korean Intellectual Property Office, the entire disclosure of which is incorporated herein by reference for all purposes.

### BACKGROUND

### Field

The present disclosure relates to a method for preparing a graphyne, a graphyne prepared by the method, and a transistor including the graphyne.

### Description of the Related Art

Two-dimensional carbon allotrope materials have received much attention in various fields, such as electrical devices, optoelectronics, energy, and catalyst applications. For example, graphene, which is a typical two-dimensional carbon allotrope material, has a disadvantage of having no band gap, but researches on semiconductor materials with more improved performance than conventional semiconductors by providing a band gap to graphene have been conducted to overcome this limitation.

Graphyne is a type of two-dimensional carbon allotrope material, and is a material including benzene rings and carbon triple bonds extending from the benzene rings. Since such graphyne has been prepared by a difficult synthesis method at a relatively high temperature only in a powder form, there were limitations in various applications and characteristic analysis of the graphyne.

One of the studies on graphdiyne (Liu, R., Gao, X., Zhou, J., Xu, H., Li, Z., Zhang, S., Liu, Z. (2017). Chemical Vapor Deposition Growth of Linked Carbon Monolayers with Acetylenic Scaffoldings on Silver Foil. Advanced Materials, 29(18), 1604665), which is the background art of the present disclosure, relates to a preparing method for 2D graphdiyne. The study requires a high temperature of 150° C. by simultaneously performing growing graphdiyne by vaporizing monomers, but a method for synthesizing graphyne at a temperature lower than the above temperature has not been reported.

### SUMMARY

According to a first aspect of the present disclosure, there is provided a method for preparing a graphyne including: supplying a precursor represented by the following Chemical Formula 1 to a chamber including a first zone and a second zone; vaporizing or subliming the precursor in the first zone; and depositing the precursor vaporized or sublimed in the second zone on a metal substrate to form the graphyne:

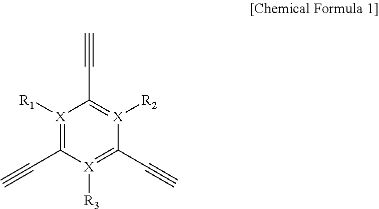

(In Chemical Formula 1, X is carbon or nitrogen, and R₁ to R₃ may be selected from the group consisting of hydrogen, bromine, fluorine, chlorine, and iodine, respectively).

According to an exemplary embodiment of the present disclosure, the precursor may be selected from the group consisting of tribromo triethynylbenzene, triethynylbenzene, triethynyl triazine, trichloro triethynylbenzene, trifluoro triethynylbenzene, and combinations thereof, but it is not limited thereto.

According to an exemplary embodiment of the present disclosure, a ratio between the number of double bonds and the number of triple bonds in the precursor may be 0.5:1 to 2:1, but it is not limited thereto.

According to an exemplary embodiment of the present disclosure, the forming the graphyne may include: binding the precursor and the metal substrate; performing a surface-coupling reaction between the precursors; and separating atoms of the substrate bound to the precursor from the substrate, but it is not limited thereto.

According to an exemplary embodiment of the present disclosure, the precursor may be supplied to the first zone or the second zone by an inert gas, but it is not limited thereto.

According to an exemplary embodiment of the present disclosure, the vaporizing or subliming the precursor in the first zone and the depositing the precursor in the second zone may be performed sequentially or simultaneously, but it is not limited thereto.

According to an exemplary embodiment of the present disclosure, the metal substrate may include at least one selected from the group consisting of Cu, Fe, Ni, Pd, Ru, Ir, Ti, Pt, Au, Ag, and combinations thereof, but it is limited thereto.

According to an exemplary embodiment of the present disclosure, the graphyne may be substituted or doped by at least one selected from the group consisting of H, N, O, F, Cl, Br, S, and combinations thereof, but it is not limited thereto.

According to an exemplary embodiment of the present disclosure, the reaction temperature in the first zone may be lower than the reaction temperature in the second zone, but it is not limited thereto.

According to an exemplary embodiment of the present disclosure, the reaction temperature of the first zone may be 30° C. to 50° C., and the reaction temperature of the second zone may be above 50° C. to 80° C., but they are not limited thereto.

According to a second aspect of the present disclosure, there is provided a graphyne prepared by the method for preparing the graphyne according to the first aspect.

According to an exemplary embodiment of the present disclosure, a ratio of the number of double bonds:the number of triple bonds in the graphyne may be 0.25:1 to 4:1, but it is not limited thereto.

According to an exemplary embodiment of the present disclosure, the graphyne may include a single-layered structure or a multi-layered stacking structure, but it is not limited thereto.

According to an exemplary embodiment of the present disclosure, in the multi-layered stacking structure, graphynes of the single-layered structure may be alternately stacked, or graphyne of an upper layer and graphyne of a lower layer may be stacked to cross each other, but it is not limited thereto.

According to a third aspect of the present disclosure, there is provided a transistor including: a substrate; a source electrode disposed on the substrate; a drain electrode disposed on the substrate and spaced apart from the source electrode; and a channel layer disposed between the source electrode and the drain electrode and including the graphyne according to the second aspect.

According to an exemplary embodiment of the present disclosure, holes on the graphyne electrically connects the source electrode and the drain electrode, but it is not limited thereto.

The above-mentioned technical solutions are merely exemplary and should not be construed as limiting the present disclosure. In addition to the above-described exemplary embodiments, additional exemplary embodiments may exist in the drawings and detailed description of the disclosure.

### BRIEF DESCRIPTION OF THE DRAWINGS

The above and other aspects, features and other advantages of the present disclosure will be more clearly understood from the following detailed description taken in conjunction with the accompanying drawings.

FIG. 1 is a schematic diagram illustrating the method for preparing the graphyne according to an exemplary embodiment of the present disclosure.

FIG. 2 is a schematic diagram illustrating an apparatus for performing the method of preparing the graphyne according to an exemplary embodiment of the present disclosure.

FIG. 3 is a schematic diagram of a surface-coupling reaction according to an exemplary embodiment of the present disclosure.

FIGS. 4A to 4D are schematic diagrams illustrating stacking patterns of the graphyne according to exemplary embodiments of the present disclosure.

FIG. 5 is a schematic diagram of the transistor according to an exemplary embodiment of the present disclosure.

FIGS. 6A and 6C are graphs showing temperatures of a first zone and FIGS. 6B and 6D are graphs showing temperatures of a second zone in the method according to an exemplary embodiment of the present disclosure.

FIG. 7A is an SEM image of graphyne according to an exemplary embodiment of the present disclosure, FIG. 7B is a Raman spectrum of the graphyne, and FIGS. 7C and 7D are X-ray photoelectron spectroscopy spectra of the graphyne.

FIG. 8A is a micrograph of graphyne according to an exemplary embodiment of the present disclosure, and FIG. 8B is an infrared spectrum of the graphyne.

FIG. 9A is an X-ray photoelectron spectroscopy spectrum of the precursor and graphyne according to an exemplary embodiment of the present disclosure, FIGS. 9B and 9C are TEM images of the graphyne, FIG. 9D is an SAED pattern of the graphyne, and FIG. 9E is a schematic diagram of a stacking pattern of the graphyne.

FIGS. 10A, 10B, 10D, and 10E are TEM images of graphyne according to an exemplary embodiment of the present disclosure, and FIGS. 10C and 10F are SAED patterns of a (222) lattice of the graphyne.

FIGS. 11A, 11C, and 11D are TEM images of graphyne according to an exemplary embodiment of the present disclosure, and FIG. 11B is an SAED pattern of the graphyne.

FIG. 12A is a TEM image of graphyne according to an exemplary embodiment of the present disclosure, and FIG. 12B is an FFT spectrum of the graphyne.

FIG. 13A is a current curve between the source electrode and the drain electrode of the transistor according to an exemplary embodiment of the present disclosure, and FIG. 13B is a graph showing a relationship between a gate voltage and a drain current of the transistor.

Throughout the drawings and the detailed description, the same reference numerals refer to the same or like elements. The drawings may not be to scale, and the relative size, proportions, and depiction of elements in the drawings may be exaggerated for clarity, illustration, and convenience.

### DETAILED DESCRIPTION OF THE EMBODIMENT

Hereinafter, exemplary embodiments of the present disclosure will be described in detail so as to be easily implemented by those skilled in the art, with reference to the accompanying drawings.

However, the present disclosure may be embodied in many different forms and is not limited to the exemplary embodiments to be described herein. In addition, parts not related with the description have been omitted in order to clearly describe the present disclosure in the drawings and throughout the present specification, like reference numerals designate like elements.

Further, throughout the present disclosure, when a certain part is “connected” with the other part, it is meant that the certain part may be “directly connected” with the other part and “electrically connected” with the other part with another element interposed therebetween.

Throughout the present disclosure, it will be understood that when a certain member is located “on”, “above”, “at the top of”, “under”, “below”, and “at the bottom of” the other member, a certain member is in contact with the other member and another member may also be present between the two members.

Throughout the present disclosure, when a certain part “comprises” a certain component, unless otherwise disclosed to the contrary, it is meant that the part may further comprise another component without excluding another component.

The terms “about”, “substantially”, and the like to be used in the present disclosure are used as a numerical value or a value close to the numerical value when inherent manufacturing and material tolerances are presented in the stated meaning, and used to prevent an unscrupulous infringer from unfairly using disclosed contents in which precise or absolute numerical values are mentioned to help in the understanding of the present disclosure. Throughout the present specification, the term “step to” or “step of” does not mean “step for”.

Throughout the present disclosure, the term “combinations thereof” included in the expression of the Markush form means one or more mixtures or combinations selected from the group consisting of components described in the expression of the Markush form, and means to include at least one selected from the group consisting of the components.

Throughout the present disclosure, “A and/or B” means “A or B, or A and B”.

Hereinafter, the method for preparing the graphyne of the present disclosure will be described in detail with reference to exemplary embodiments, Examples, and drawings. However, the present disclosure is not limited to these exemplary embodiments, Examples, and drawings.

An object to be achieved by the present disclosure is to provide a method for preparing graphyne with a large area and a graphyne prepared by the method.

Further, another object to be achieved by the present disclosure is to provide a transistor including the graphyne.

Objects of the present disclosure are not limited to the above-mentioned objects, and other objects, which are not mentioned above, can be clearly understood by those skilled in the art from the following descriptions.

Conventional graphyne has been studied theoretically, and was synthesized only in a powder form, thus having difficulty to be used in actual industrial fields.

However, according to the exemplary embodiment of the present disclosure, in the method for preparing graphyne, a surface-coupling reaction between benzene-acetylene-based monomers and a substrate is induced through a chemical vapor deposition method, which has not been used in a conventional preparing method for graphyne to synthesize graphyne as a 2-dimensional material layer, thereby adjusting the size and thickness of a graphyne film.

Specifically, the surface-coupling reaction is induced on the surface of a metal substrate to suppress the synthesis of a 1-dimensional or 3-dimensional material, thereby enabling the synthesis of a 2-dimensional material. In addition, the size of the metal substrate is adjusted to adjust the size of the prepared graphyne and facilitate the transfer to another substrate.

In addition, it is possible to provide a method for synthesizing two-dimensional carbon allotropes connected by several types of single or multiple single carbon triple bonds, substituted with hydrogen or nitrogen.

In addition, while sublimating or vaporizing the monomer molecules, the sublimated or vaporized monomers are disposed on the metal substrate at the same time, thereby reducing the time required for synthesizing graphyne.

In addition, the transistor including the graphyne prepared by the method according to the present disclosure includes a channel layer having carbon triple bonds to be usable as a biosensor that easily adsorbs ionic biomaterials and does not require a fluorescent label.

The effects according to the present disclosure are not limited to the effects exemplified above, and more various effects are included in the present specification.

As a technical means to achieve the technical object, a first aspect of the present disclosure relates to a method of preparing graphyne including: supplying a precursor represented by the following Chemical Formula 1 to a chamber including a first zone and a second zone; vaporizing or subliming the precursor in the first zone; and depositing the precursor vaporized or sublimed in the second zone on a metal substrate to form graphyne:

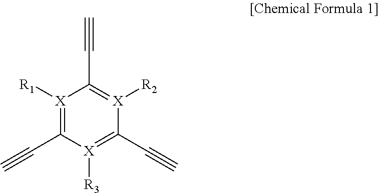

(In Chemical Formula 1, X is carbon or nitrogen, and R₁ to R₃ may be selected from the group consisting of hydrogen, bromine, fluorine, chlorine, and iodine, respectively).

The graphyne according to the present disclosure consists of triple bond (sp) and double bond (sp2) carbon atoms arranged in a crystal lattice, has a planar structure with an atomic thickness, and includes at least one of the materials represented by the following Structural Formula 1 as a lattice of benzene rings connected by acetylene bonds:

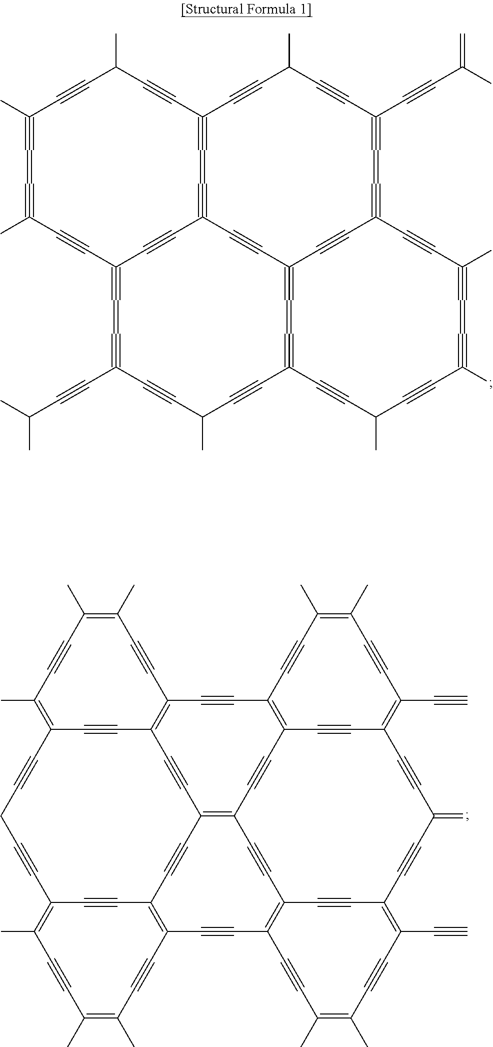

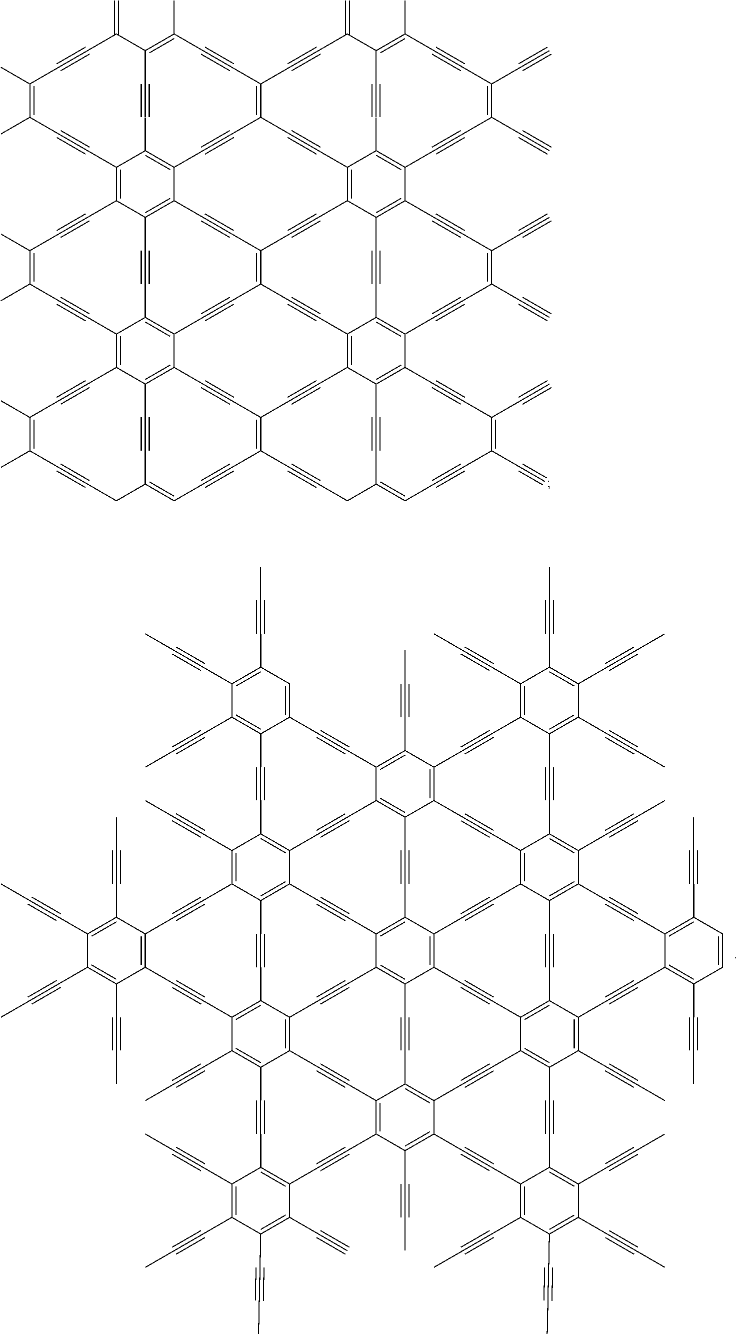

In this regard, graphynes of Structural Formula 1 refer to alpha-graphyne, beta-graphyne, 6,6,12-graphyne, and gamma graphyne in the above order from the top.

Unlike graphene, in which carbon atoms form a two-dimensional planar structure, since the graphyne includes triple bonds, the graphyne is difficult to grow into a two-dimensional structure because the precursor is unstable and side reactions may occur during the preparing process, so that the graphyne was prepared in a powder form in a conventional method for preparing graphyne.

However, the method of preparing a graphyne according to the present disclosure uses a surface-coupling reaction between a precursor of graphyne and a metal substrate, and unlike the conventional method, graphyne may be synthesized through a chemical vapor deposition method.

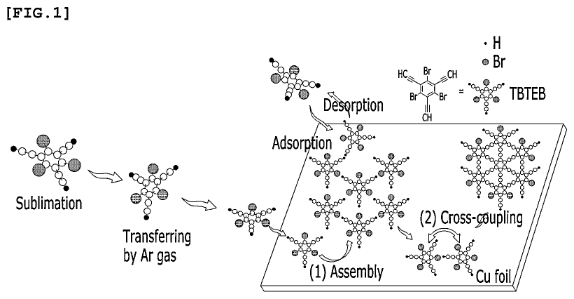

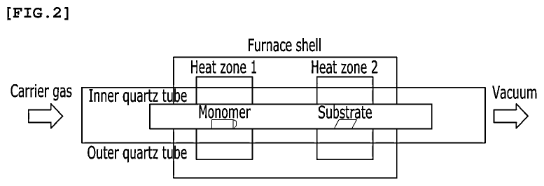

FIG. 1 is a schematic diagram illustrating the method according to an exemplary embodiment of the present disclosure and FIG. 2 is a schematic diagram illustrating an apparatus for performing the method according to an exemplary embodiment of the present disclosure.

Referring to FIG. 1, a vaporized monomer (e.g., tribromo triethynylbenzene (TBTEB)) may be surface-coupled with a metal substrate to prepare graphyne.

First, the precursor represented by Chemical Formula 1 is supplied to the chamber including the first zone and the second zone.

According to an exemplary embodiment of the present disclosure, the precursor may include at least one selected from the group consisting of tribromo triethynylbenzene, triethynylbenzene, triethynyl triazine, trichlorotriethynylbenzene, trifluorotriethynylbenzene, and combinations thereof, but it is not limited thereto. Specifically, the precursor may include at least one of the materials represented by the following Structural Formula 2:

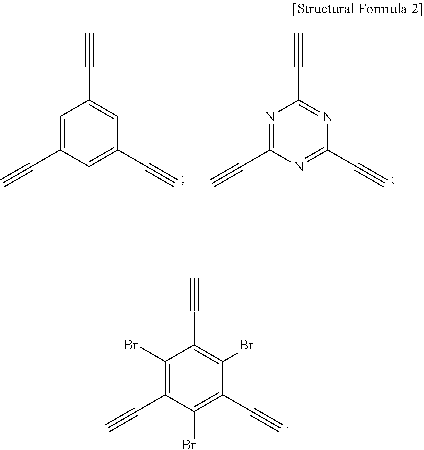

According to an exemplary embodiment of the present disclosure, a ratio between the number of double bonds and the number of triple bonds in the precursor may be 0.5:1 to 2:1, but it is not limited thereto.

The precursor has triethynylbenzene as a basic structure, in which the number of double bonds and the number of triple bonds are the same. Although as described below, double bonds included in the benzene ring of the precursor, single-binding carbons extending from the benzene ring, and triple-binding carbons extending from the single-binding carbons are maintained, and precursor molecules may be bound to other precursor molecules through the surface-coupling reaction with the substrate.

Next, the precursor is vaporized or sublimed in the first zone.

According to an exemplary embodiment of the present disclosure, the precursor may be supplied to the first zone or the second zone by an inert gas, but it is not limited thereto. For example, the precursor may be transferred to the first zone or the second zone by the inert gas such as Ar, Ne, He, or the like.

In this regard, a flow rate of the inert gas may be 100 sccm to 200 sccm, but it is not limited thereto.

Next, the precursor vaporized or sublimed in the second zone is deposited on the metal substrate to form the graphyne.

According to an exemplary embodiment of the present disclosure, the forming of the graphyne may include binding the precursor and the metal substrate, performing a surface-coupling reaction between the precursors, and separating atoms of the substrate bound to the precursor from the substrate, but it is not limited thereto. Specifically, the coupling reaction may occur by binding between an ethynyl group of the precursor bound to the metal substrate and a benzyl group of another precursor, or between a benzyl group bound to the metal substrate and an ethynyl group of another precursor.

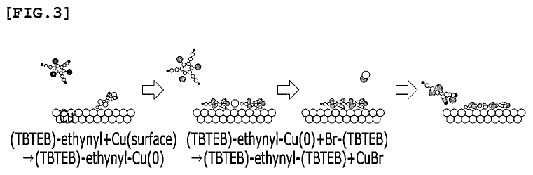

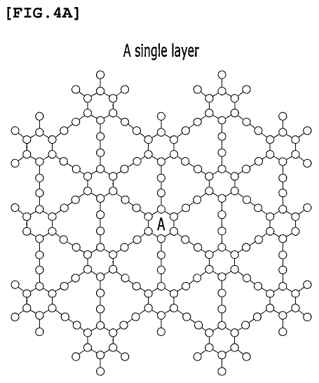

FIG. 3 is a schematic diagram of a surface-coupling reaction according to an exemplary embodiment of the present disclosure. For example, the method for preparing the graphyne, when the precursor is tribromo triethynylbenzene (TBTEB) and the metal substrate is Cu, is described with reference to FIG. 3. In FIG. 3, an ethynyl group of the TBTEB reacts with Cu so that the ethynyl group of the TBTEB binds to Cu (TETEB-ethynyl-Cu(0)). At this time, the TBTEB bound to Cu reacts with a Br group of another TBTEB molecule, and tribromo triethynylbenzene is bound through an ethynyl group, that is, a triple bond, and the Cu, which has been bound to the TBTEB, is bound to the Br group to be released from the substrate or the TBTEB.

In addition, when the precursor is triethynylbenzene (TEB), hydrogen is separated from an ethynyl group of the TEB through a reaction of the ethynyl group of the TEB with Cu, and the ethynyl group of the TEB is bound to an ethynyl group of another TEB, so that a homo-coupling phenomenon may occur.

In addition, when the precursor is triethynyl triazine (TETA), hydrogen is separated from an ethynyl group of the TETA through a reaction of the ethynyl group of the TETA with Cu, and the ethynyl group of the TETA is bound to an ethynyl group of another TETA, so that a homo-coupling phenomenon may occur.

In this regard, when the precursor is TETEB, the synthesized graphyne may be gamma-graphyne, and when the precursor is TEB or TETA, the synthesized graphyne may be graphdiyne, but it is not limited thereto.

According to an exemplary embodiment of the present disclosure, the vaporizing or subliming of the precursor in the first zone and the depositing of the precursor in the second zone on the substrate to form the graphyne may be performed sequentially or simultaneously, but it is not limited thereto.

According to an exemplary embodiment of the present disclosure, the reaction temperature in the first zone may be lower than the reaction temperature in the second zone, but it is not limited thereto.

According to an exemplary embodiment of the present disclosure, the reaction temperature of the first zone may be 30° C. to 50° C., and the reaction temperature of the second zone may be above 50° C. to 80° C., but it is not limited thereto.

In the method for preparing the graphyne according to the present disclosure, since the temperature for the sublimation or vaporization of the precursor and the temperature of graphyne are very low, in order to suppress side reactions or decomposition of the precursor occurring during the synthesis of the graphyne, the vaporizing or sublimating of the precursor and the forming of the graphyne may be performed sequentially or simultaneously.

The sequential performing of the vaporizing or sublimating of the precursor and the forming of the graphyne means separate growth of the graphyne. The separate growth is a method of synthesizing graphyne by collecting and growing the vaporized or sublimated precursors on the metal substrate by raising the temperature of the second zone after all precursors are vaporized or sublimed to complete movement to the metal substrate.

When the vaporizing or sublimating of the precursor and the forming of the graphyne are sequentially performed, a graphyne film of a large-area thin layer may be synthesized, and the degree of contamination of the surface of the substrate, in which the graphyne is synthesized, is low, but graphyne having a small crystal size may be synthesized.

The simultaneously performing the vaporizing or sublimating of the precursor and the forming of the graphyne means simultaneous growth of the graphyne. In the simultaneous growth, the vaporizing or sublimating of the precursor in the first zone, the moving of the vaporized or sublimated precursor, and the synthesis of the graphyne on the metal substrate are simultaneously performed by raising the temperature of the first zone and the temperature of the second zone, simultaneously.

When the vaporizing or sublimating of the precursor and the forming of the graphyne are simultaneously performed, a graphyne film of a small-area thick layer may be synthesized, and the degree of contamination of the surface of the substrate, in which the graphyne is synthesized, may be increased, but graphyne having a large crystal size may be synthesized.

According to an exemplary embodiment of the present disclosure, the metal substrate may include at least one selected from the group consisting of Cu, Fe, Ni, Pd, Ru, Ir, Ti, Pt, Au, Ag, and combinations thereof, but it is not limited thereto.

According to an exemplary embodiment of the present disclosure, the graphyne may be substituted or doped by at least one selected from the group consisting of H, N, O, F, Cl, Br, S, and combinations thereof, but it is not limited thereto.

The method for preparing the graphyne may be performed by chemical vapor deposition method, and when gas such as H₂, N₂, O₂, F₂, and Cl₂ is supplied during the preparing process, some of the carbons or hydrogens of graphyne may be substituted with H, N, O, F, and Cl, or H, N, O, F, and Cl may be doped into the graphyne structure.

According to an exemplary embodiment of the present disclosure, single-layered graphyne may be formed on the substrate, but it is not limited thereto.

According to an exemplary embodiment of the present disclosure, the method may further include transferring the formed graphyne, but it is not limited thereto.

The graphyne may be formed through a homo-coupling reaction between ethynyl groups of the precursor through a surface reaction with the metal substrate and a cross-coupling reaction between an ethynyl group of the precursor and a benzyl group of another precursor. Since the surface-coupling reaction does not occur between the graphyne formed on the substrate and the precursor, single-layered graphyne may be formed on the metal substrate. However, the method for preparing the graphyne according to the present disclosure may include transferring the single-layered graphyne formed on the metal substrate to an upper part of another graphyne to form multi-layered graphyne.

In addition, when the temperature is increased while the precursors sublimated in the first zone of the substrate are aggregated and arranged and the precursors sublimed even in the second zone different from the first zone are aggregated and arranged, the precursors of the first zone and the precursors of the second zone may be grown. At this time, due to a difference in growth rate, etc., graphyne growth in the first zone may be tilted so as to be grown on the precursor growing in the second zone.

In this regard, when graphyne is synthesized on the metal substrate, the graphyne may act as a template to further synthesize graphyne on the graphyne. Specifically, a crystal of the lower graphyne may act as a template for the growth of the upper graphyne. Multi-layered graphyne may be grown by coupling reaction binding between precursors through metal atoms of the metal substrate, but the size of the crystal of the synthesized graphyne may be small, and the thickness of the graphyne film may be determined according to the degree of defects in the crystal of the lower graphyne.

A second aspect of the present disclosure provides the graphyne prepared by the method for preparing the graphyne according to the first aspect.

According to an exemplary embodiment of the present disclosure, a ratio of the number of double bonds and the number of triple bonds in the graphyne may be 0.25:1 to 4:1, but it is not limited thereto.

Specifically, when the graphyne is synthesized by TBTEB (gamma-graphyne), the number ratio of double bonds and triple bonds of the graphyne may be 1:1. However, when the graphyne is synthesized by TEB or TETA (graphdiyne), the number ratio of double bonds and triple bonds of the synthesized graphyne may be 1:2.

As described above, the graphyne may have Structural Formula 1 above. At this time, the double bonds in the graphyne may exist only in the benzene ring. However, since the number of single and triple bonds increases as the number of carbons between the benzene rings increases and as a distance between the benzene rings in the graphyne increases, the number of triple bonds relative to the number of double bonds may increase.

In this regard, as the number of triple bonds in graphyne increases, the conductivity and the charge mobility of the graphyne film may increase, and a band gap may decrease. At this time, since the number of triple bonds in the graphyne is determined according to the spacing between the benzene rings, graphdiyne, which has two triple bonds, instead of gamma-graphyne, which has one triple bond, may be synthesized by modifying the precursor, or graphyne is synthesized by using a precursor of trichloro triethynylbenzene, and the like formed with Cl instead of Br of TETEB so that cross coupling does not occur, thereby synthesizing graphyne with the increased number of triple bonds.

According to an exemplary embodiment of the present disclosure, the graphyne may include a single-layered structure or a multi-layered stacking structure, but it is not limited thereto.

As described above, the graphyne formed on the metal substrate by the method of preparing graphyne according to the present disclosure may be basically a single-layered material. However, the graphyne formed on the metal substrate may be transferred to the surface of another graphyne to prepare graphyne having a multi-layered structure.

According to an exemplary embodiment of the present disclosure, in the multi-layered stacking structure, graphynes of the single-layered structure are alternately stacked, or graphyne of an upper layer and graphyne of a lower layer are stacked to cross each other, but it is not limited thereto.

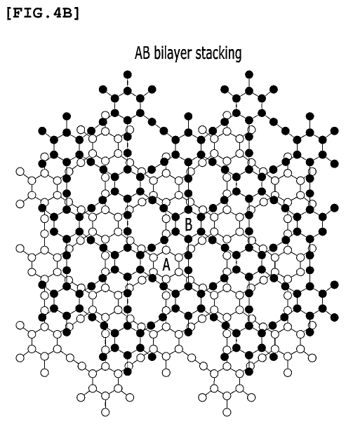

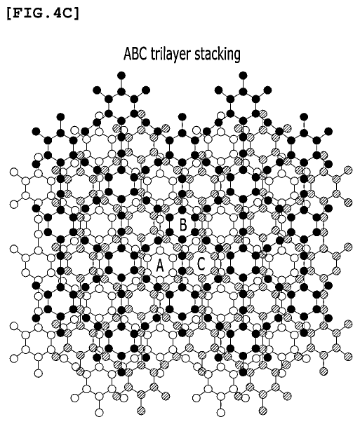

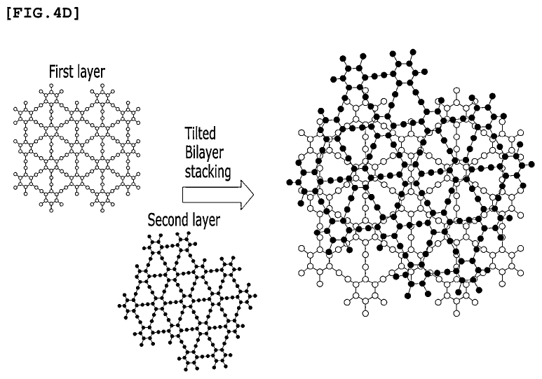

FIGS. 4A to 4D are schematic diagrams illustrating stacking patterns of graphyne according to an exemplary embodiment of the present disclosure. Specifically, FIG. 4A illustrates single-layered graphyne, FIG. 4B illustrates bi-layered graphyne stacked in an AB pattern, FIG. 4C illustrates triple-layered graphyne stacked in an ABC pattern, and FIG. 4D illustrates graphyne, in which the upper and lower layers are stacked to cross each other.

In this regard, as the stacking degree of the graphynes increases, the conductivity of a film, on which the graphynes are stacked, may also increase, but the band gap may also decrease. When the stacking degree of the graphyne exceeds a predetermined value, a conduction band and a valence band meet each other in a cone shape to have an energy band structure of a semi-metal.

A third aspect of the present disclosure relates to a transistor including a substrate, a source electrode disposed on the substrate, a drain electrode disposed on the substrate and spaced apart from the source electrode, and a channel layer disposed between the source electrode and the drain electrode and including the graphyne according to the second aspect.

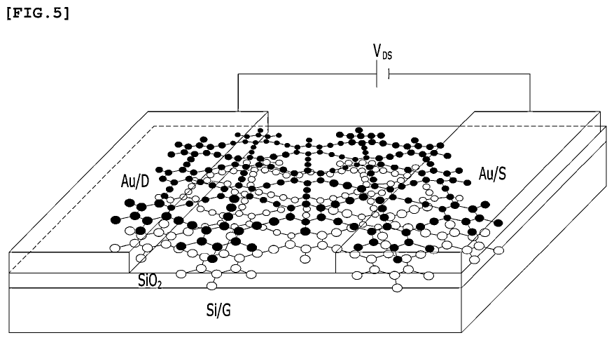

FIG. 5 is a schematic diagram of the transistor according to an exemplary embodiment of the present disclosure.

According to an exemplary embodiment of the present disclosure, the channel layer may be formed by transferring single-layered or multi-layered graphyne on the substrate using poly(methyl methacrylate) (PMMA) before or after forming the source electrode and the drain electrode on the substrate.

According to the exemplary embodiment of the present disclosure, the electrical connection between the source electrode and the drain electrode may be caused by a hole on the graphyne, but it is not limited thereto. For example, gamma-graphyne in which the graphyne is formed of a single layer may have a p-type semiconductor property.

However, the electrical properties of the graphyne may be changed according to a thickness of the graphyne.

Although described below, when a voltage is applied between the source electrode and the drain electrode of the transistor including graphyne as the channel layer, conductivity in a μA unit is exhibited, and when a gate voltage is applied, it can be confirmed that the current flows due to holes.

Hereinafter, the present disclosure will be described in more detail with reference to the following Examples, but the following Examples are only for illustrative purposes and are not intended to limit the scope of the present disclosure.

### Example 1-1

1,3,5-tribromo-2,4,6-triethynylbenzene (TBTEB) was injected into a first zone of a chamber, where a copper foil was disposed in a second zone. Next, the TBTEB was sublimed at 40° C. for 4 hours, and Ar flowed at 150 sccm to move the sublimated TBTEB to the second zone. Next, the temperature of the second zone was raised to 60° C. to 80° C., and the sublimated TBTEB reacted with a copper substrate to prepare graphyne.

### Example 1-2

In Example 1-1, the raising of the temperature of the second zone was performed simultaneously with the sublimating of TBTEB in the first zone.

### Example 2

A graphyne layer grown through chemical vapor deposition method was transferred onto a SiO₂ substrate using a PMMA coating method and then dried. Then, PMMA was removed with acetone, and an FET device was prepared.

### Experimental Example 1

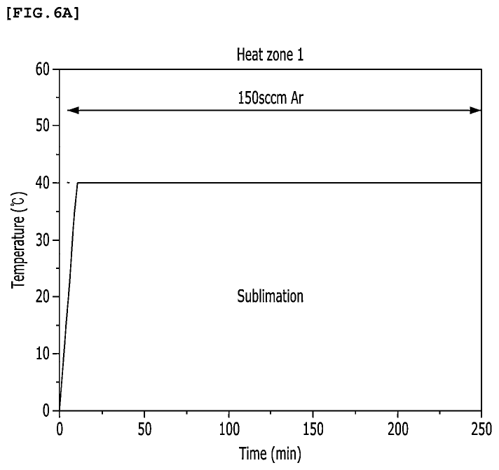

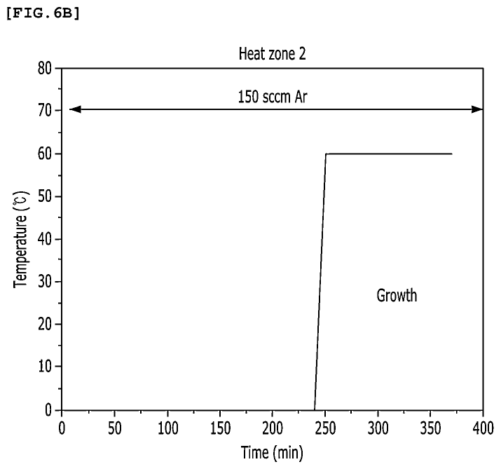

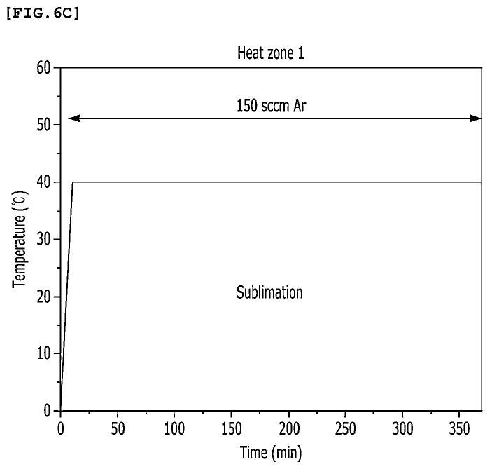

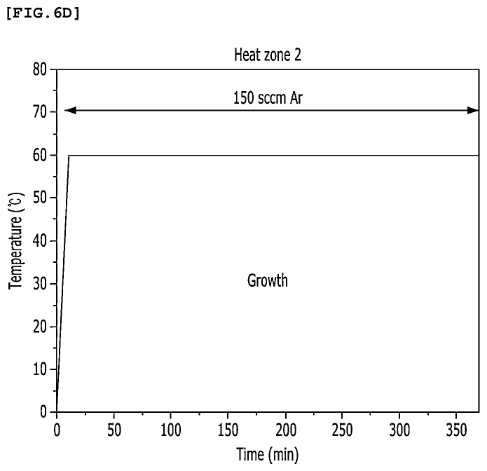

FIGS. 6A and 6C are graphs showing temperatures of a first zone and FIGS. 6B and 6D are graphs showing temperatures of a second zone in the method of preparing the graphyne according to an exemplary embodiment of the present disclosure. Specifically, FIGS. 6A and 6B illustrate temperatures of the first zone and the second zone in the method of Example 1-1, and FIGS. 6C and 6D illustrate temperatures of the first zone and the second zone in the method of Example 1-2.

Referring to FIG. 6, Example 1-1 represents a method of separately growing graphyne, and Example 1-2 represents a method of simultaneously growing graphyne.

Specifically, in the method of Example 1-1, TBTEB, which was sublimated and moved for the first 4 hours, was deposited by interaction with a copper substrate, and only aggregation and arrangement occurred at room temperature. At this time, when the sublimation for 4 hours was finished and the temperature of the second zone was raised to 60° C., surface cross-coupling occurred between carbon triple bonds of TBTEB and bromine using copper ions as a catalyst, and the deposited TBTEB was desorbed and adsorbed to grow graphyne.

In addition, in the method of Example 1-2, the temperature of the second zone was raised to 60° C. while the sublimation was performed in the first zone, and the TBTEB sublimated in the first zone was deposited on the copper substrate and then aggregated and arranged, and immediately, the surface cross-coupling occurred using copper ions as a catalyst.

### Experimental Example 2

The graphynes of Examples 1 and 2 were analyzed.

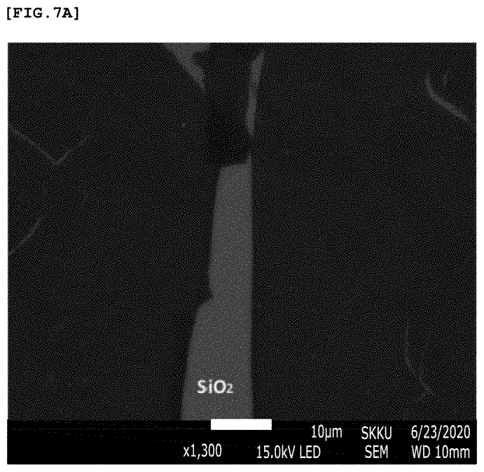

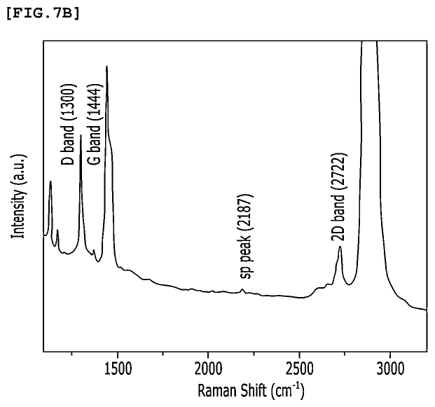

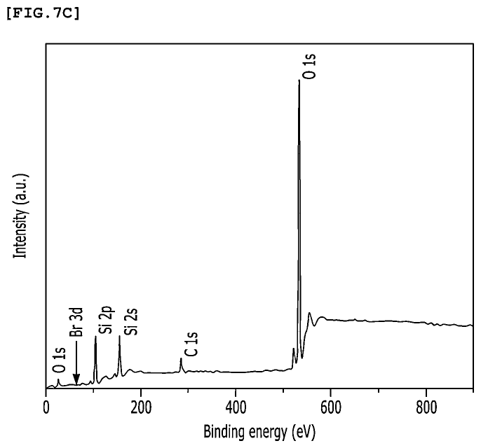

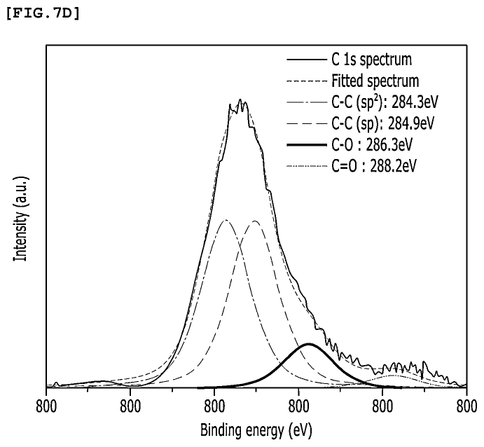

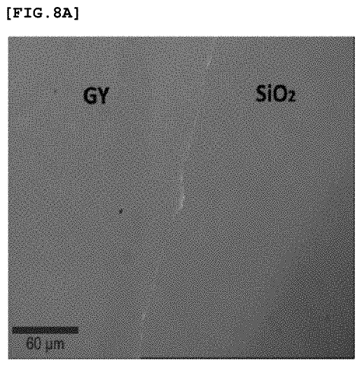

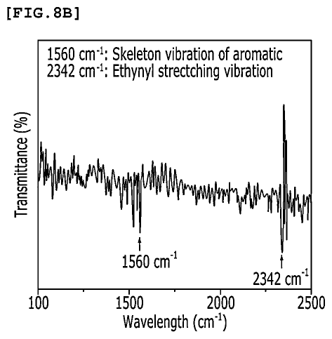

FIG. 7A is an SEM image of graphyne according to Example, FIG. 7B is a Raman spectrum of the graphyne, and FIGS. 7C and 7D are X-ray photoelectron spectroscopy spectra of the graphyne. FIG. 8A is a micrograph of graphyne according to an exemplary embodiment of the present disclosure, and FIG. 8B is an infrared spectrum of the graphyne. In this regard, O is peaks and C—O peaks of FIGS. 7C and 7D are caused by SiO₂, on which the graphyne is stacked, and the C—O peaks are generated by oxidation of the graphyne.

Referring to FIGS. 7 and 8, graphyne on a silicon substrate may have a signal of a G band derived from a benzene ring, a D band containing information such as a substitution degree, a defect, and an oxidation degree of the benzene ring, a 2D band determined by the degree of crystallinity of the material, or the like. At this time, through the 2D band, it can be seen that the graphyne has crystallinity, and a single sp peak is identified, so that a coupling reaction between a carbon triple bond and bromine occurs instead of a homogeneous coupling reaction between carbon triple bonds to generate carbon single bond-triple bond.

In addition, in the process of synthesizing the graphyne, oxygen binding energy may be observed from oxidation of TBTEB or graphyne itself, oxygen of silicon derived when all surfaces are not deposited on the surface of the substrate of a defective graphyne layer, oxygen in the atmosphere, to which the graphyne is adsorbed, and the like. It can be seen that a composition ratio of sp carbon bonds and sp2 carbon bonds is 1:1, and that the synthesized material is graphyne through skeletal vibration of aromatics, stretching vibration of ethynyl, and the like.

### Experimental Example 3

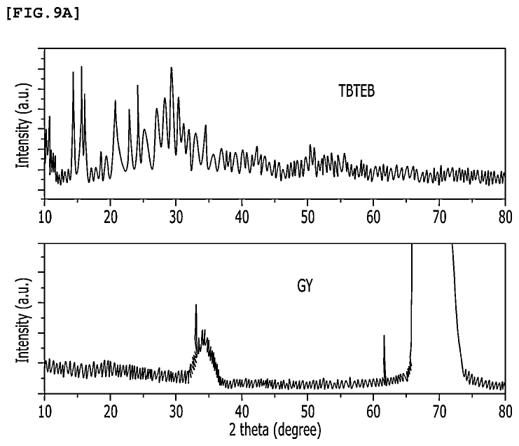

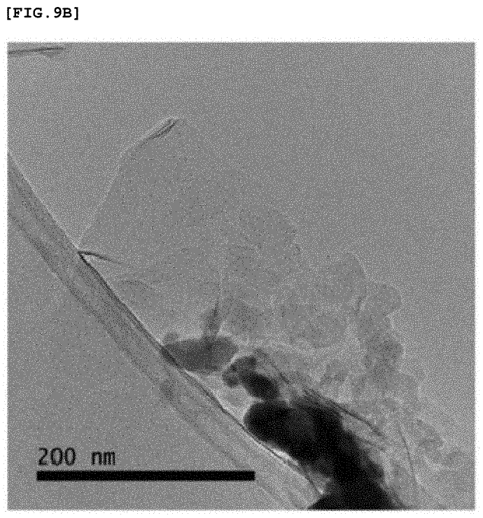

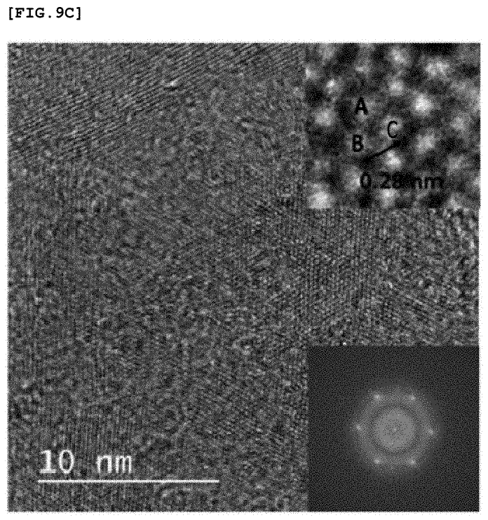

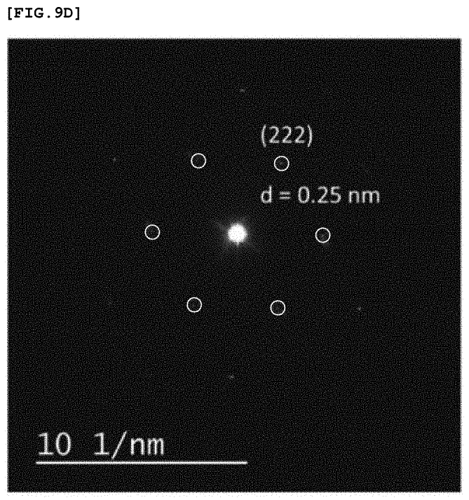

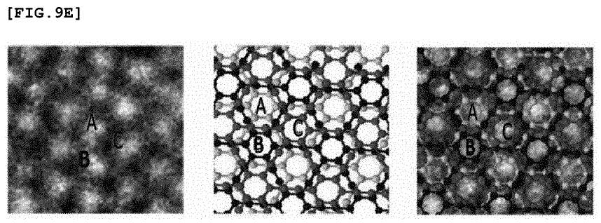

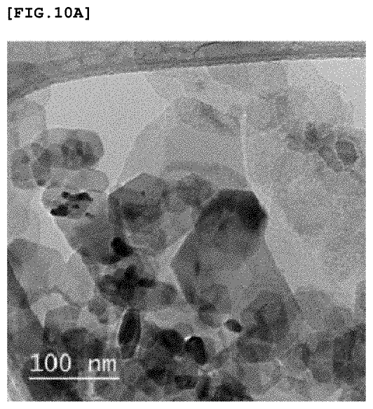

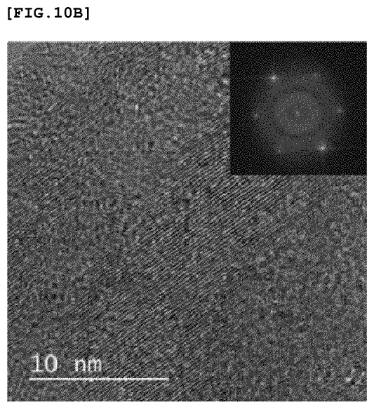

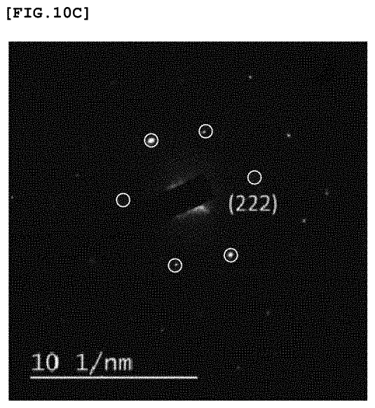

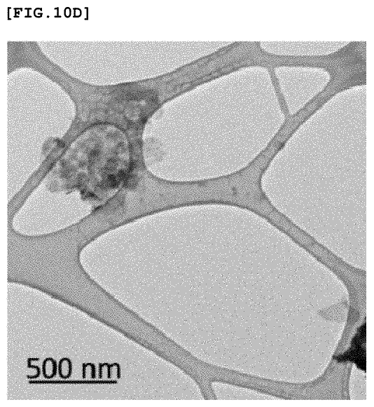

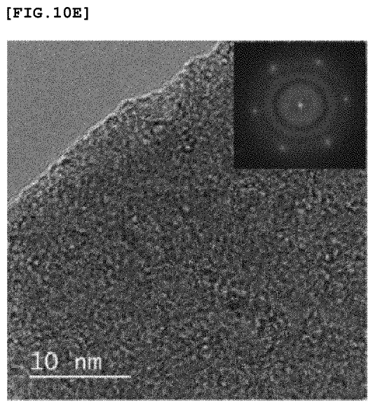

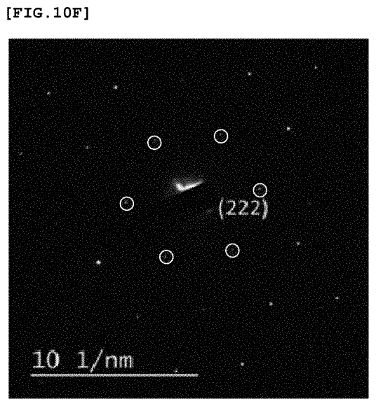

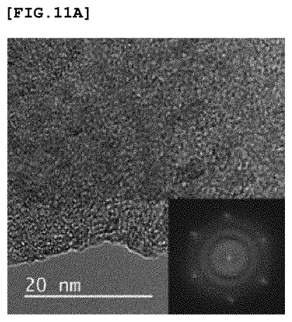

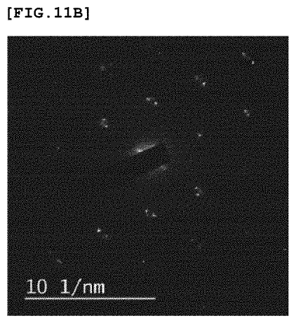

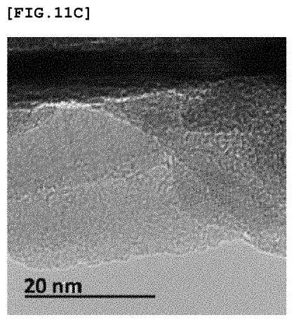

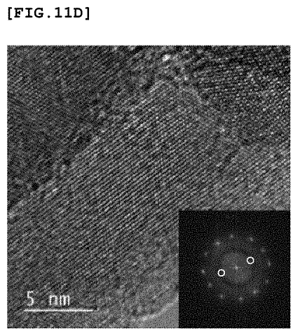

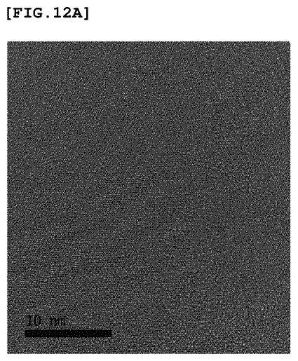

FIG. 9A is an X-ray photoelectron spectroscopy spectrum of a precursor and graphyne according to an exemplary embodiment of the present disclosure, FIGS. 9B and 9C are TEM images of the graphyne, FIG. 9D is an SAED pattern of the graphyne, and FIG. 9E is a schematic diagram of a stacking pattern of the graphyne. FIGS. 10A, 10B, 10D, and 10E are TEM images of graphyne according to an exemplary embodiment of the present disclosure, and FIGS. 10C and 10F are SAED patterns of a (222) lattice of the graphyne. FIGS. 11A, 11C, and 11D are TEM images of graphyne according to an exemplary embodiment of the present disclosure, and FIG. 11B is an SAED pattern of the graphyne.

Specifically, FIG. 9, FIGS. 10A to 10C, and FIGS. 11A and 11B illustrate graphynes grown at 60° C. after sublimating TBTEB at 40° C., FIGS. 10D to 10F illustrate graphynes grown at 80° C., and FIGS. 11C and 11D illustrate graphynes grown at 80° C.

In addition, the drawing inserted in the upper part of FIG. 9C illustrates that graphyne has been stacked in an ABC pattern, the drawings inserted in the lower part of FIG. 9C and inserted in FIG. 11A illustrate FFT patterns of graphyne, and the drawings inserted in FIGS. 10B and 10E and FIG. 11D illustrate FFT patterns meaning a (222) lattice of graphyne.

Referring to FIGS. 9 to 11, the graphyne grown at 80° C. shows a hexagonal pattern that is more obscured in the FFT pattern than the graphyne grown at 60° C., which means that the upper layer of graphyne was grown to be tilted at a greater angle or alternately with respect to the lower layer.

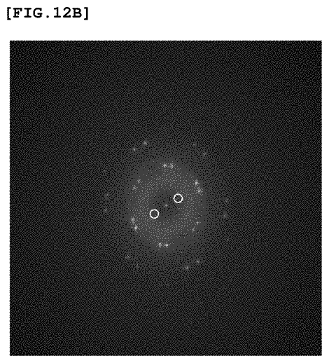

FIG. 12A is a TEM image of graphyne according to an exemplary embodiment of the present disclosure, and FIG. 12B is an FFT spectrum of the graphyne. In this case, a red circle of FIG. 12B means a (110) lattice plane.

Referring to FIGS. 7 to 12, it can be confirmed that the synthesized graphyne may be formed in a plate shape, not a powder form.

### Experimental Example 4

Electrical characteristics of the transistor prepared by the method according to Example 2 were analyzed.

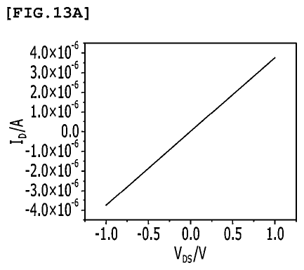

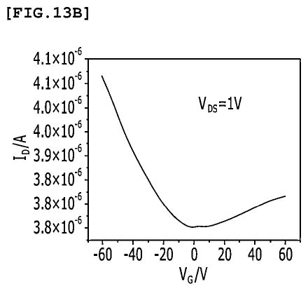

FIG. 13A is a current curve between a source electrode and a drain electrode of a transistor according to Example 2, and FIG. 13B is a graph showing a relationship between a gate voltage and a drain current of the transistor.

Referring to FIG. 13, as a result measured in a V_{S-D} range of −1 V to 1 V, it can be seen that a drain current of the transistor has a unit of μA. In addition, when a gate voltage of −60 V to +60 V is applied to the transistor, the drain current changes greatly when the gate voltage is negative, but the drain current changes small when the gate voltage is positive. Through this, it can be confirmed that the transistor including the graphyne has a characteristic of a p-type voltage-current curve.

The aforementioned description of the present disclosure is to be exemplified, and it will be understood by those skilled in the art that the present disclosure can be easily modified in other detailed forms without changing the technical spirit or required features of the present disclosure. Therefore, it should be appreciated that the embodiments described above are illustrative in all aspects and are not restricted. For example, respective components described as single types can be distributed and implemented, and similarly, components described to be distributed can also be implemented in a coupled form.

The scope of the present disclosure is represented by appended claims to be described below rather than the detailed description, and it is to be interpreted that the meaning and scope of the claims and all the changes or modified forms derived from the equivalents thereof come within the scope of the present disclosure.

What is claimed is:

1. A method for preparing a graphyne comprising:
supplying a precursor represented by the following Chemical Formula 1 to a chamber comprising a first zone and a second zone;
vaporizing or subliming the precursor in the first zone; and
depositing the precursor vaporized or sublimed in the second zone on a metal substrate to form the graphyne: 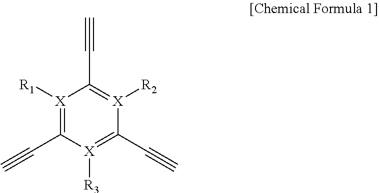
(in Chemical Formula 1, X is carbon or nitrogen, and R₁ to R₃ are selected from the group consisting of hydrogen, bromine, fluorine, chlorine, and iodine, respectively).

2. The method of claim 1, wherein the precursor is selected from the group consisting of tribromo triethynylbenzene, triethynylbenzene, triethynyl triazine, trichloro triethynylbenzene, trifluoro triethynylbenzene, and combinations thereof.

3. The method of claim 2, wherein a ratio between a number of double bonds and a number of triple bonds in the precursor is 0.5:1 to 2:1.

4. The method of claim 1, wherein the forming of the graphyne comprises:
binding the precursor and the metal substrate;
performing a surface-coupling reaction between the precursors; and
separating atoms of the substrate bound to the precursor from the substrate.

5. The method of claim 1, wherein the precursor is supplied to the first zone or the second zone by an inert gas.

6. The method of claim 1, wherein the vaporizing or subliming the precursor in the first zone and the depositing the precursor in the second zone are performed sequentially or simultaneously.

7. The method of claim 1, wherein the metal substrate comprises at least one selected from the group consisting of Cu, Fe, Ni, Pd, Ru, Ir, Ti, Pt, Au, Ag, and combinations thereof.

8. The method of claim 1, wherein the graphyne is substituted or doped by at least one selected from the group consisting of H, N, O, F, Cl, Br, S, and combinations thereof.

9. The method of claim 1, wherein a reaction temperature in the first zone is lower than a reaction temperature in the second zone.

10. The method of claim 9, wherein the reaction temperature in the first zone is 30° C. to 50° C., and of the reaction temperature in the second zone is above 50° C. to 80° C.

11. A graphyne prepared by the method of claim 1.

12. The graphyne of claim 11, wherein a ratio of a number of double bonds:a number of triple bonds in the graphyne is 0.25:1 to 4:1.

13. The graphyne of claim 11, wherein the graphyne comprises a single-layered structure or a multi-layered staking structure.

14. The graphyne of claim 13, wherein in the multi-layered stacking structure, graphynes of the single-layered structure are alternately stacked, or graphyne of an upper layer and graphyne of a lower layer are stacked to cross each other.

15. A transistor comprising:
a substrate;
a source electrode disposed on the substrate;
a drain electrode disposed on the substrate and spaced apart from the source electrode; and
a channel layer disposed between the source electrode and the drain electrode and comprising the graphyne of claim 11.

16. The transistor of claim 15, wherein holes on the graphyne electrically connects the source electrode and the drain electrode.
